(19) United States
(12) Patent Application Publication
(10) Pub. No.: US 2003/0150643 A1
(43) Pub. Date: Aug. 14, 2003

(54) Layout for noise reduction on a printed circuit board and connectors using it

(76) Inventors: Eric Juntwait, Harrisburg, PA (US); David F. Givens, Harrisburg, PA (US)

Correspondence Address: WEI TE CHUNG, FOXCONN INTERNATIONAL, INC., 1650 MEMOREX DRIVE, SANTA CLARA, CA, 95050, US

(21) Appl. No.: 10/075,356

(22) Filed: Feb. 13, 2002

(51) Int. Cl. H05K 1/11

(52) U.S. Cl. 174/261; 361/777

(57) ABSTRACT

A printed circuit board (1) includes a plane substrate (10) having several insulated layers (11, 12, 13) used to dispose with conductive material. A row of footprints (2) used to connect to other electrical devices is disposed on an outer insulated layer (11) of the printed circuit board (1). These footprints (2) are paired and each is connected to a medial trace (5) formed on one of the intermediate layers (12) by a metalized hole (14). And the medial traces (C1, C1′) respectively connected to footprints (2) of the same pair (T1, R1) are formed on different intermediate layers (12) and aligned with each other for a predetermined distance. At least two traces (C3, C3′) connected to the chosen pair (T3, R3) are detoured to pass through a corresponding area aligned with the footprints (2) of their adjacent pair (T2, R2) mounted on the upper face (11) and are formed a corresponding footprint (R3′, T3′) over there respectively, so that the corresponding footprint (R3′, T3′) can be coupled with the footprints (T3, R3) to improve the noised signals received by the chosen pair (T3, R3) and its adjacent pair (T2, R2).

### BACKGROUND OF THE INVENTION

1. Field of the Invention

The present invention is related to a layout on a printed circuit board for reducing noise or cross talk between two parallel-transmission signal conductors, especially to a printed circuit board can be used in a connector assembly with a conditioning parts including magnetic filter components mounted on the printed circuit board to condition the signals passing through the connector assembly.

2. Description of the related art

The digital communication between electronic device like computers becomes more and more important because of the prevalence of the Internet. People join a network to the Internet or a local area network through connecting cables or wireless equipments. However, before a better standards and reasonable price for wireless equipments can be established, the most important intermediary for people to connect to a network is still a cable/wire and the connector to mate with them. In high frequency and speed situation usually demanded by modern people, the reliability of signal transmission through these cables and connectors is very crucial to get a clear and precise signal after a long distance transmission. Usually the noise from the environment cables meet and cross talk between two parallel signal-transmitting conductors are the most undesired derivative in the transmission. Therefore, if signals can be conditioned before they are received by any electronic device, the performance and working speed of this device will be fast and more accurate. A conditioning-use component, such as a common mode choke coil, filter circuit or transformer, can be mounted on a printed circuit board install inside an electronic device or an I/O connector of these devices. And the layout or conductive traces on/in the printed circuit board will helps to reduce or eliminate the undesired noise. In such a prior art electrical connector using differential signal pairs, the pair to pair cross talk which arises in cables or electrical connectors due to closely spaced elongated parallel conductors or contacts is reduced by modifying certain circuit paths either inside or outside of the connector. That means one each conductor of one pair which is parallel to and cross talking with an adjacent conductor of another pair is relocated adjacent and parallel to the other conductor of this another pair over a predetermined distance. So, the noise arisen in the connector by said conductor of the adjacent pair is compensated on the printed circuit board right away by the other conductor of the same adjacent pair. However, the arrangement is easy to achieve when two signal differential pairs are considered only. The more pairs are used, the more complicate compensating circuits on the printed circuit board are needed. Especially, as mentioned above, more than one conditioning electronic component is going to be mounted on the printed circuit board to condition the signals pass through them. And enough coupling distance of the adjacent pairs should be designed if significant electrical performance is demanded. It is obviously easily understood that more space on the printed circuit board will be needed to achieve these electrical performances. And the difficulty to assemble such a connector will rise when a larger printed circuit board is adopted.

Using multi-layer printed circuit boards is one of the solutions to simplify the processes to make a miniaturized connector. But it costs expensive if a printed circuit board is designed to have too many necessary conductive layers to meet the need. Besides, it is difficult too if more than one connectors share the same printed circuit board serving as its conditioning part without increasing the size or layers of the printed circuit board. The copending application 10/041,101 having the same assignee with the invention, disclose some approach for implementation.

### SUMMARY OF THE INVENTION

Therefore, an object of the present invention is to provide a layout of a printed circuit board to save space occupied by compensating circuits and avoid the need of increasing the size or layers of the printed circuit board.

Another object of the present invention is to provide a layout of a printed circuit board that has definitely and enough coupling areas for better compensating performance automatically before a preserved space is designed for this performance in advance.

Another object of the present invention is to provide a layout of a printed circuit board that can be used in common for at least two connecting portions to contribute to making a miniaturized and highly-integrated connecting assembly.

A further object of the present invention is to provide a layout of a printed circuit board to reduce the possible noise between two differential signal pairs by separating them from each other as far as possible in the limited space of the printed circuit board.

To obtain the above objects, a printed circuit board includes a plane substrate having several insulated layers used to dispose with conductive material. A row of footprints used to connect to other electrical devices is disposed on an outer insulated layer of the printed circuit board. These footprints are paired and each is connected to a medial trace formed on one of the intermediate layers by a metalized hole. And the medial traces respectively connected to footprints of the same pair are formed on different intermediate layers and aligned with each other for a predetermined distance, so that these two traces of the same pair are moved closer to each other and far away from any other pair to stabilize their signal transmission.

Specifically. At least two traces connected to the chosen pair are detoured to pass through a corresponding area aligned with the footprints of their adjacent pair mounted on the upper face and are formed a corresponding footprint over there respectively, so that the corresponding footprint can be coupled with the footprints of the adjacent pair to improve the signals received by the chosen pair and its adjacent pair while the signals borne on these pairs of footprints are noised each other due to closely spaced parallel transmission in said other electrical devices. To use the footprints for signal compensation instead of conductive traces benefits space-saving and miniaturization of a printed circuit board. Besides, to modify the size of the footprints for compensating according to the distance between the footprints and their coupling footprints will get better electrical performance.

Other objects, advantages and novel features of the invention will become more apparent from the following detailed description of the present embodiment when taken in conjunction with the accompanying drawings.

### BRIEF DESCRIPTION OF THE DRAWINGS

FIG. 1 is a plane view of a printed circuit board in accordance with the present invention;

FIG. 2 is a sectional view of the printed circuit board showing conductors therein along the 2-2 line in FIG. 1;

FIG. 3 is a sectional view of the printed circuit board showing conductors therein along the 3-3 line in FIG. 1;

FIG. 4 is a plane view of a second printed circuit board in accordance with the present invention;

FIG. 5 is a sectional view of the printed circuit board showing conductors therein along the 5-5 line in FIG. 4;

FIG. 6 is a plane view of a third printed circuit board in accordance with the present invention;

FIG. 7 is a sectional view of the printed circuit board showing conductors therein along the 7-7 line in FIG. 6;

FIG. 8 is an explosive view of a multi-port connector assembly using a printed circuit board in accordance with the present invention as a part of its conditioning unit.

### DESCRIPTION OF THE PREFERRED EMBODIMENT

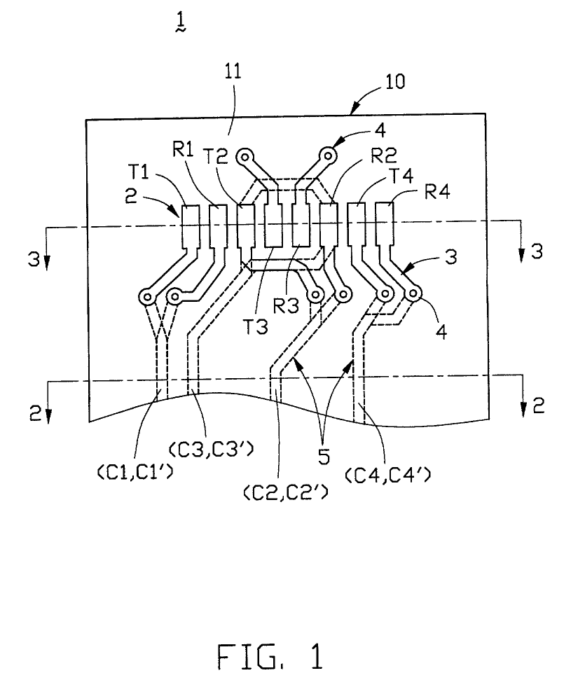

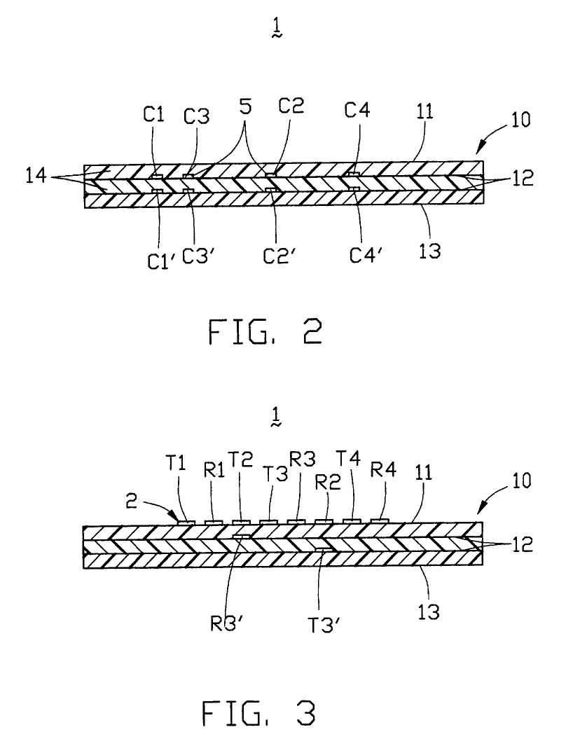

Referring to FIGS. 1, 2 and 3, the present invention is related to the layout on a printed circuit board 1 used to reduce noise. The printed circuit board 1 has a plane substrate 10 including at least three insulated layers to be disposed with conductive material, the outer ones formed as an upper face 11 and lower face 13, and intermediate layers 12. An insulative layer 14 is sandwiched between every two of the insulated layers. Besides, a row of footprints 2 used to connect to other electrical devices, especially referred to quadrate conductive pads, is disposed on the upper face 11 of the printed circuit board 1. According to the signal transmission frequency and speed standard, these connectable footprints 2 are arranged as several differential pairs. In this embodiment, the two footprints T1, R1, T4, R4 at both ends of this row and the middle two footprints T3, R3 of this row are paired. And the remained footprints T2, R2, the third and sixth ones in the row, are paired. Each connectable footprint is integrally connected to a metalized hole 14 extending through the insulative layer 14 adjacent to the upper face 11 from the upper face 11 to one of intermediate layers 12 by a conductive trace 3 formed on the upper face 11. Meanwhile, the extending end of every metalized hole 14 is integrally connected to a medial trace 5 formed on one of the intermediate layers 12 to further connect to other portions of the printed circuit board 1 or electronic components mounted on the printed circuit board 1. Besides, footprints 2 of the same pair connect to one of medial traces 5 formed on different intermediate layers 12 respectively. For example, the footprint T1 (T2, T3, T4) of one pair connects to the medial trace C1 (C2, C3, C4) form on one intermediate layer 12 while the other footprint R1 (R2, R3, R4) of the same pair connects to the medial trace C1′ (C2′, C3′, C4′) of another intermediate layer 12. And portions of these paired two medial traces C1, C1′ (C2, C2′, C3, C3′ and C4, C4′) are aligned with each other over a predetermined length in the normal direction of intermediate layers. In the arrangement, the signal transmission paths for every differential pair T1, R1 (T2, R2, T3, R3, T4, R4) can be moved closer to each other and farther away from the transmission paths of any other pair. Thus the signal transmission for each differential pair is stabilized and less pair to pair noise will rise.

Referring to FIGS. 1 and 3, the medial traces 5 connect to a chosen pair (T3, R3 for example) are used to compensate the pair to pair noise which arises in electrical devices like cables or electrical connectors due to their parallel arranged conductors. The traces C3, C3′ connected to the chosen pair T3, R3 and extending from the end of their corresponding metalized holes 4 on the intermediate layers 12 are detoured to pass through a corresponding area next to footprints 2 of the adjacent pair T2, R2 mounted on the upper face 11 and are formed with corresponding footprints R3′, T3′ over there. The corresponding footprint R3′, T3′ connected to the chosen pair R3, T3 is parallel to the footprint of the adjacent pair T2, R2 and signals passing through the footprints T2, R2 can be compensated due to coupling with the footprints T3, R3′, R3, T3′ of the chosen pair at the same time. It is understandable that only the neighborhood area of the footprints 2 is occupied by compensating circuits. And the predetermined length of every footprint 2 needed to connect to the corresponding conductors of the electrical devices is long enough for better compensating performance. Therefore space-saving and miniaturization of a built-in printed circuit board can be easily achieved.

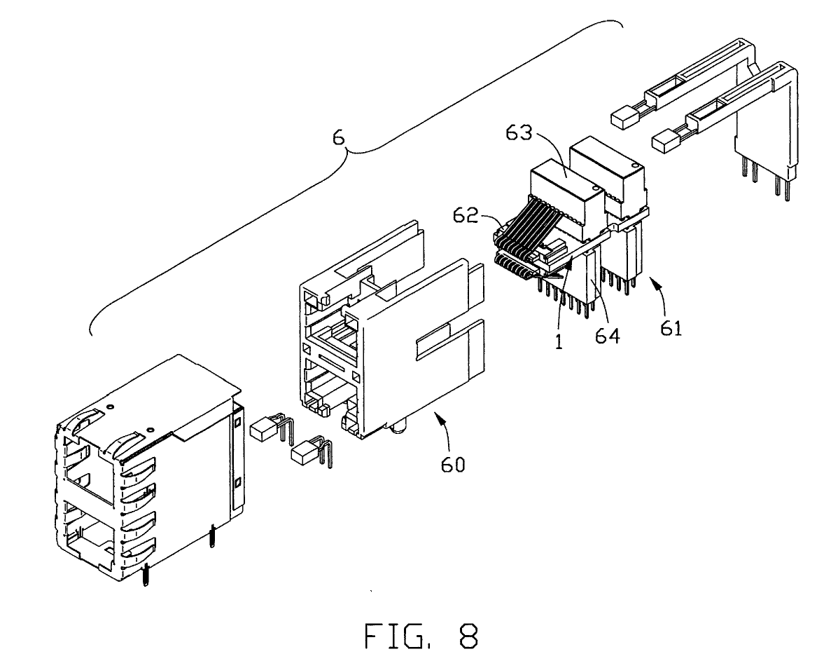

Refernng to FIG. 8, a built-in printed circuit board 1 in accordance with the present invention is installed in a connector assembly 6. The connector assembly 6 has two stacked mating ports formed by an integrated housing 60. The printed circuit board 1 is inserted into the housing 60 from its rear side and positioned in its middle portion. Two terminal modules 62 with insert-molded terminals formating are mounted and soldered onto both sides of the printed circuit board 1 near its insertion leading edge. And two corresponding conditioning components 63 and tail module 64 are mounted onto the printed circuit board 1 respectively to form a conditioning unit 61 before assembling. It is obvious the size and price of the printed circuit board 1 is a key to the relative size and cost of this connector assembly. And the layout of the printed circuit board will be simplified in accordance with the present invention by repeatedly using the footprints 2 where the terminals of the connector assembly 6 are soldered and separating the compensating circuits from the traces connecting to the conditioning components 63 and tail module 64.

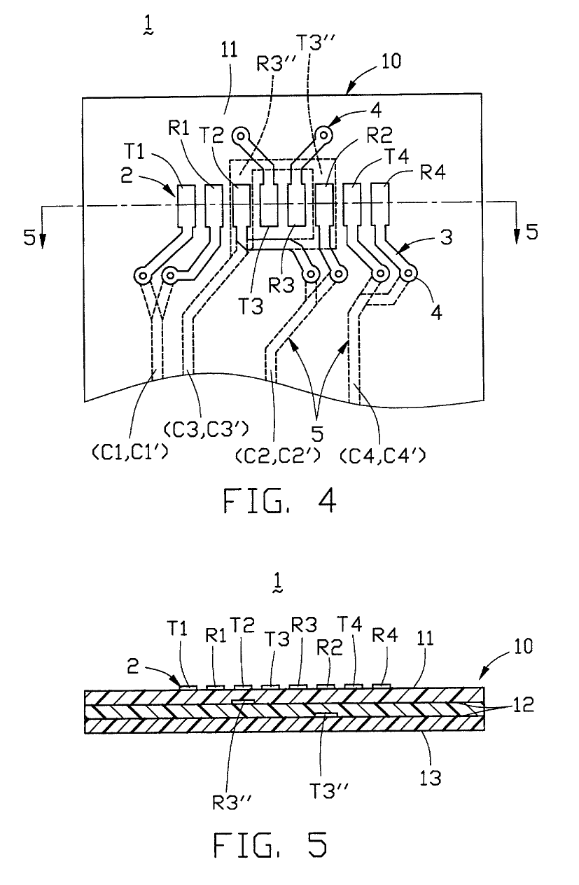

Referring to FIGS. 4 and 5, a second embodiment of the printed circuit board in accordance with the present invention is shown. An enlarged footprint R3″, T3″ instead of the footprint R3′, T3′ having the same size as footprint 2 is respectively formed along the traces C3, C3′ on intermediate layers 12 which are connected to the chosen pair T3, R3 and detoured to pass through a corresponding area next to footprints 2 of the adjacent pair T2, R2. Better electrical performance will be achieved because a larger coupling area is available respectively with the enlarged footprint R3″, T3″ and the adjacent pair T2, R2 to assure of complete noise compensation.

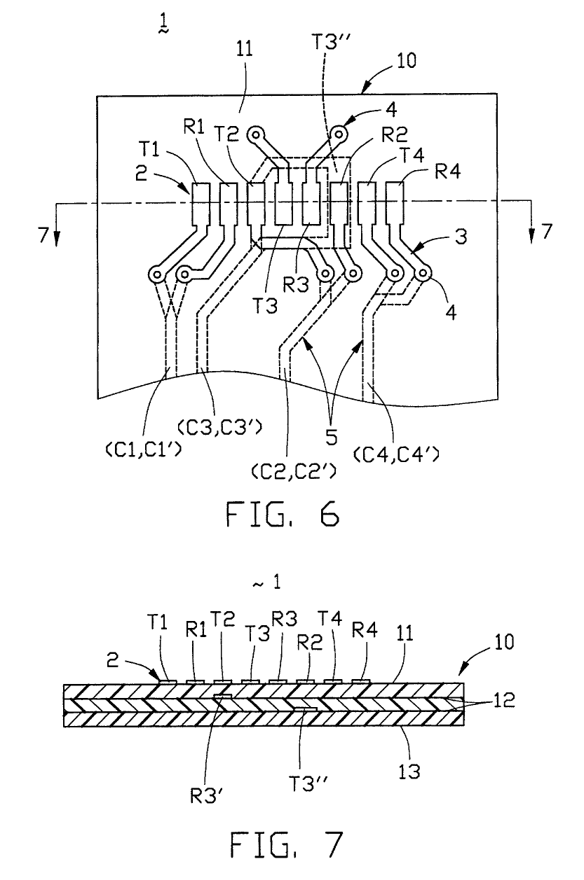

Referring to FIGS. 6 and 7, a third embodiment of the printed circuit board in accordance with the present invention is shown. The trace C3 on the intermediate layer 12 right next to the upper face 11 of the substrate 10 has a compensating footprint R3′ formed on the corresponding parallel area of the intermediate layer 12 to one of the footprints 2 of the pair T2, R2 on the upper face 11, and the compensating footprint R3′ has the same size as its coupling footprint T2 of the pair T2, R2. Besides, the trace C3′, which is on the intermediate layer 12 right next to the lower face 13, has an enlarged footprint T3″ formed on the corresponding parallel area of this intermediate layer 12 to the other footprint R2 of the pair T2, R2. The size of the compensating footprints R3′ and T3″ is decided by the distance between the intermediate layers 12 they are mounted and the upper face 11 where their coupling paired footprints T2, R2 are mounted. The coupling footprints R2, T3″ having a larger distance therebetween are designed to have an enlarged compensating footprint T3″. Better electrical performance than fore-mentioned two embodiments will be achieved while not only a larger coupling area is available from the enlarged footprint T3″ and its coupling footprint R2 but also a new balance of signal compensation between these coupling pair R2, T3″ and T2, R3′ will be established.

It is to be understood, however, that even though numerous characteristics and advantages of the present invention have been set forth in the foregoing description, together with details of the structure and function of the invention, the disclosure is illustrative only, and changes may be made in detail, especially in matters of shape, size, and arrangement of parts within the principles of the invention to the full extent indicated by the broad general meaning of the terms in which the appended claims are expressed.

What is claimed is:

1. A noise reduced printed circuit board comprising:
a substrate having at least two insulated layers for mounting conductive material;
a first set of conductive footprints being mounted on one of the insulated layers, each footprint of said first set being accessible from outside of the substrate and electrically connectable with a conductor extending from an electrical device, said first set of footprints being paired as the conductors in the electrical device while at least two unpaired conductors, the first and second conductor, are closely spaced from and cross talked with each other; and
a second set of conductive footprints each being located on an area of another insulated layers aligned with and spaced from one footprint of the first set and connected to another footprint of the first set; wherein
said one footprint of the first set is connected with the first conductor, and said another footprint of the first set is connected with a third conductor which is of the same pair as the second conductor.

2. The printed circuit board as recited in claim 1, wherein at least two conductive footprints of the second set are located on different insulated layers.

3. The printed circuit board as recited in claim 2, wherein footprints of the second set located on the nearer insulated layer to the layer where the first set of footprints is located have the same size as their corresponding aligned footprints of the first set, while footprints of the second set located on the farther insulated layer from the layer where the first set of footprints is located have an enlarged size larger than their corresponding aligned footprints of the first set.

4. The printed circuit board as recited in claim 3, wherein footprints of the first set are totally vertically aligned with their corresponding aligned footprints of the second set.

5. The printed circuit board as recited in claim 1, wherein each footprint of the second set has the same size as its corresponding aligned footprint of the first set.

6. The printed circuit board as recited in claim 5, wherein each footprint of the second set is totally vertically aligned with its corresponding aligned footprint of the first set.

7. The printed circuit board as recited in claim 1, wherein each footprint of the second set has an expanding size larger than its corresponding aligned footprint of the first set.

8. The printed circuit board as recited in claim 1, wherein every two footprints of the second set are connected to the same pair of footprints of the first set.

9. The printed circuit board as recited in claim 1, wherein each footprint of the first set is a solderably conductive pad.

10. The printed circuit board as recited in claim 1, wherein the printed circuit board is a built-in circuit board of a connector and all the necessary electronic components of the connector including conditioning component and terminal module are soldered on the printed circuit board.

11. A layout of a printed circuit board for noise reduction comprising:
a plurality of footprints being mounting on an outer face of a substrate of the printed circuit board, every two of said footprints being a signal-based pair when every footprints are electrically connected with a corresponding conductor from an electrical device;
a plurality of connecting conductive traces each being electrically connected to one footprint, portions of every trace extending along at least one intermediate layer located in the substrate of the printed circuit board for easiness to be electrically connected to other functional circuit of the printed circuit board; wherein
each trace connected to a first chosen pair of footprints is relocated to have portion of them pass through an area of the intermediate layer vertically spaced from the location of one footprint of a second chosen pair on the outer face of the substrate and an expanded conductive footprint is formed over there to couple with the footprint it faces.

12. The layout of the printed circuit board as recited in claim 11, wherein the expanded conductive footprint connected to one footprint of the first chosen pair is coupled with the footprint of the second chosen pair which bears a coupled signal from the electrical device when the conductor connected to said footprint of the second chosen pair is coupled with the conductor connected to the other footprint of the first chosen pair before the signals are transferred to the corresponding footprints.

13. The layout of the printed circuit board as recited in claim 11, wherein at least one expanding conductive footprints has the same size as its coupling footprint mounted on the outer face.

14. The layout of the printed circuit board as recited in claim 11, wherein at least one expanding conductive footprints has a size larger than its coupling footprint mounted on the outer face.

15. The layout of the printed circuit board as recited in claim 11, wherein the substrate has at least two different intermediate layers and at least one conductive trace portion extends along every intermediate layer.

16. The layout of the printed circuit board as recited in claim 15, wherein the expanding conductive footprints located at one intermediate layer far from the outer face has a size larger than its coupling footprint mounted on the outer face, and the expanding conductive footprints located at the other intermediate layer near the outer face has the same size as its coupling footprint mounted on the outer face.

17. A connector assembly having at least two mating ports to be engaged with a mating connector respectively, comprising:
a substrate having an electrical circuit layout on at least two insulated layers;
electronic components being electrically mounted on the substrate, at least one electronic component being used for each of the mating ports and having at least first and second pairs of conductors inside, one conductors of the first pair being closely parallel to and cross talked with one conductor of the second pair; wherein
said layout has two sets of footprints used to connect with the paired conductors from the electronic components of each mating port, and said two sets of footprints are located on a different insulated layer of the substrate respectively, the footprint connected with said one conductor of said first pair of the electronic component couples with one footprint of a third set which is electrically connected to the footprint where the other conductor of said second pair not cross talked with said one conductor of said first pair is connected.

18. A printed circuit board comprising:
a substrate having at least two insulated layers;
a plurality of footprints being mounting on one insulated layer of the substrate of the printed circuit board, every two of said footprints being a signal-based pair when every footprints are electrically connected with a corresponding conductor from an electrical device;
a plurality of connecting conductive traces each being electrically connected to one footprint, the traces connected respectively to every footprint of one chosen pair being located on two different insulated layers; wherein
said traces located on two different insulated layers are aligned with each other along a predetermined distance.

19. A printed circuit board having conductive traces arrangement for reducing cross-talk therebetween, including
a substrate defining at least three mounting surfaces;
a first conductive trace including first, second and third sections;
a second conductive trace including first, second and third sections;
a third conductive trace including first, second and third sections; and
wherein the first section of the first, second and third conductive traces are all arranged in a common mounting surface;
wherein the second section of the first conductive trace is arranged in a second mounting surface and in align with the first section of the second conductive trace;
wherein the third section of the first conductive trace is align with the third section of the third conductive trace.

20. A printed circuit board comprising:
first, second and third layers stacked one another;
first, second, third and fourth traces side by side located on the first layer in sequence, said first trace and said fourth trace being a differential pair, and said second trace and said third trace being another differential pair;
a fifth trace located on the second layer, vertically aligned with the first trace and electrically connected to the third trace for somewhat counterbalancing crosstalk between the first trace and the second trace generated around the first layer; and
a sixth trace located on the third layer, vertically aligned with the fourth trace and electrically connected to the second trace for somewhat counterbalancing crosstalk between the third trace and the fourth trace generated around the first layer; wherein
a distance between the first layer and the second layer is different from that between the first layer and the third layer, and a size of said fifth trace and that of the said sixth trace are dimensioned according to those distances.
